(19) United States
(12) Patent Application Publication
(10) Pub. No.: US 2007/0090479 A1
(43) Pub. Date: Apr. 26, 2007

(54) Controlling bond fronts in wafer-scale packaging

(76) Inventors: Chien-Hua Chen, Corvallis, OR (US); Kirby Sand, Corvallis, OR (US); Bradley Charles John, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/254,875

(22) Filed: Oct. 20, 2005

(51) Int. Cl. H01L 31/0203; H01L 21/77

(52) U.S. Cl. 257/433; 438/455; 438/64; 257/723

(57) ABSTRACT

A system for controlling bond front propagation in wafer-scale packaging includes a first substrate, a second substrate, and a bonder pressure plate having protruded structures thereon to selectively establish at least one point of contact between the first and second substrates to initiate a bond front therebetween. The protruded structures are selectively configured to control the propagation of the bond front.

### BACKGROUND

Microelectromechanical systems (MEMS) are micron-size devices widely used in many electronic applications, such as televisions, projection systems, and other optical applications. MEMS devices are created using micro machining processes like those used to produce integrated circuits. This allows two or three dimensional mechanical systems to be created in the same small area typical of an integrated circuit. Because the manufacturing processes are similar to an integrated circuit, MEMS devices are most often created on semiconductor wafers. In this way, thousands of MEMS devices can be fabricated onto a single wafer.

Semiconductor wafers are often fabricated (i.e., packaged) using a bonding technique known as plasma-enhanced bonding. During plasma-enhancement, the mating surfaces of the semiconductor wafers are subjected to a brief plasma treatment and then further processed prior to being assembled. Semiconductor substrates joined by plasma-enhancement are bonded directly at the atomic level with robust covalent bonds. In the case of MEMS packaging for optical applications, a glass substrate is bonded directly to an MEMS optical wafer to hermetically seal all MEMS devices contained therein. The plasma bonding process begins at the point of contact between the two substrates. In other words, a bond front that seals the substrates together propagates from the point of contact between the glass and the optical MEMS wafer until the entire area between the glass and optical wafer is bonded. Therefore, for purposes of this application, a bond front refers to the leading edge of the bonding process as it propagates to join two substrates.

A known approach to wafer bonding includes a wafer bonding machine that assembles the glass substrate to the optical wafer using a generally planar pressure plate. Generally, the bonding machine bows the center of the glass substrate so that when the glass and the optical wafer are assembled together by the pressure plate, the initial point of contact between them is at the center. In this way, the propagation of the bond front starts at the center of the wafer and propagates outward. This method works well for some bonding techniques; however, for pre-trenched glass substrates that are often used in optical MEMS applications, the trenches in the glass interrupt the bond front making the bond front propagation chaotic and unpredictable. In other words, when a portion of a propagating bond front reaches a trench, the trench tends to form a barrier that prevents further propagation of that portion of the bond front. Further, when a bond front stalls at a trench, but continues to propagate in other sections of the wafer, the bond front begins to propagate in multiple directions causing uncontrolled propagation. In many cases, the uncontrolled bond front results in trapped air pockets between the MEMS optical wafer and the glass substrate. The air pockets can cause hermeticity or optical issues and ultimately degrade the optical interface quality of the resulting MEMS device.

The embodiments described hereinafter were developed in light of these and other drawbacks associated with bond front propagation in wafer-scale packaging.

### BRIEF DESCRIPTION OF THE DRAWINGS

The present embodiments will now be described, by way of example, with reference to the accompanying drawings, in which:

FIG. 1A illustrates an optical wafer with a pre-trenched glass substrate with an initiated bond front;

FIG. 1B illustrates the progression of the bond front propagation according to the optical wafer of FIG. 1A;

FIG. 1C illustrates an optical wafer with trapped air pockets;

FIG. 2 illustrates a partial side view of an assembled wafer according to an embodiment;

FIG. 3 illustrates an exemplary embodiment of a bonder pressure plate having protruded structures arranged according to a grid-like array;

FIG. 4 illustrates an exemplary embodiment of a bonder pressure plate having protruded structures arranged into wedges separated by vent grooves;

FIG. 5 illustrates an exemplary embodiment of a bonder pressure plate having protruded structures in a line pattern;

FIG. 6 illustrates an exemplary embodiment of a bonder pressure plate having protruded structures arranged in a ring and line pattern; and

FIG. 7 illustrates an exemplary embodiment of a bonder pressure plate having protruded structures in a raised ring pattern.

### DETAILED DESCRIPTION

A generally planar bonder pressure plate having protruded structures for controlling bond fronts in wafer-scale packaging is provided. Wafer-scale packaging generally involves initiating a point of contact between two substrates using a bonder pressure plate. In an exemplary embodiment, the protruded structures on the bonder pressure plate are configured to selectively initiate bond fronts in selected areas of the wafer to control the bond front propagation. By selectively initiating the points of contact and controlling the bond fronts, air pockets due to uncontrolled multiple bond fronts are reduced.

The bonder pressure plates disclosed herein are used in conjunction with a variety of bonding techniques, including, but not limited to plasma-enhanced and hydrophilic bonding. However, for purposes of illustration, the bonder pressure plates disclosed herein are explained with reference to a plasma-enhanced bonding application.

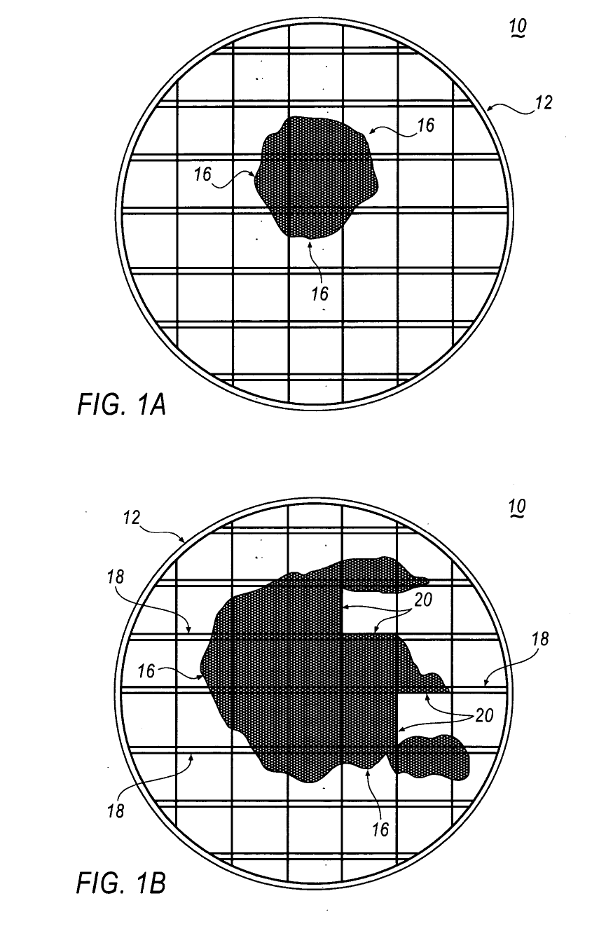

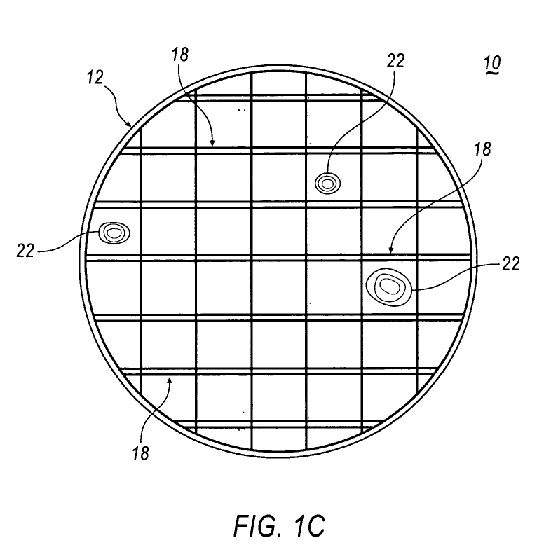

FIGS. 1A-1C collectively illustrate the effects of a known technique for plasma-enhanced bonding using a pre-trenched glass substrate and a flat pressure plate. For example, a top view of an optical wafer 10 having a pre-trenched glass substrate 12 is shown in FIG. 1A. Assume for purposes of this illustration that the pre-trenched glass substrate 12 was bowed at the center prior to being assembled onto a MEMS optical substrate (not shown) such that the initial point of contact is approximately the center of the wafer 10. In this configuration, the bond front 16 propagation initiates outward from the center of the wafer 10. Ideally, the bond front 16 would propagate outward from the center so that the leading edges of the bond front 16 approach the outer edge of the wafer 10 at approximately the same time providing a substantially continuous and uniform bond throughout the wafer 10.

Unfortunately, as shown in FIG. 1B, in the case of a pre-trenched glass substrate 12 the trenches 18 in the glass substrate 12 intermittently interrupt the bond front 16 as the bond front propagates through the wafer 10 causing a chaotic and uncontrolled propagation. As further illustrated in both FIGS. 1B and 1C, this uncontrolled bond front 16 surrounds the areas of the wafer where the bond front has been interrupted 20 causing trapped air pockets 22 that degrade the optical quality of the resulting wafer and compromise the effectiveness of the bond seal.

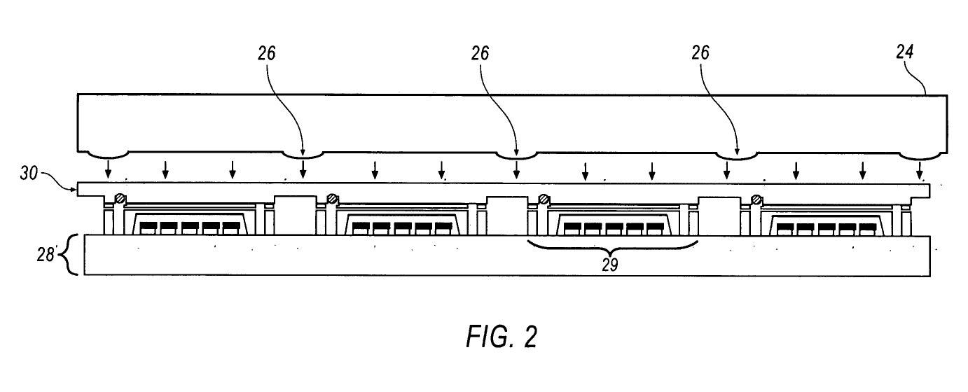

Referring to FIG. 2, the exemplary method for controlling bond fronts disclosed herein provides for a bonder pressure plate 24 having selectively positioned protruded structures 26 configured to initiate select points of contact between two substrates to control bond front propagation. As shown in FIG. 2, the bonder pressure plate 24 is used to assemble an optical MEMS wafer 28 to a pre-trenched glass substrate 30. In one embodiment, an optical MEMS wafer 28 comprises an array of individual dies 29 that generally include a plurality of microelectromechanical devices, such as, but not limited to, diffractive light devices (DLDs). The size, shape, position, and overall configuration of the protruded structures 26 on the bonder pressure plate 24 may vary depending on the precise application and substrates used. Therefore, as one of ordinary skill in the art understands, the arrangement of the protruded structures on the bonder pressure plate is not limited to the exemplary bonder pressure plates described herein.

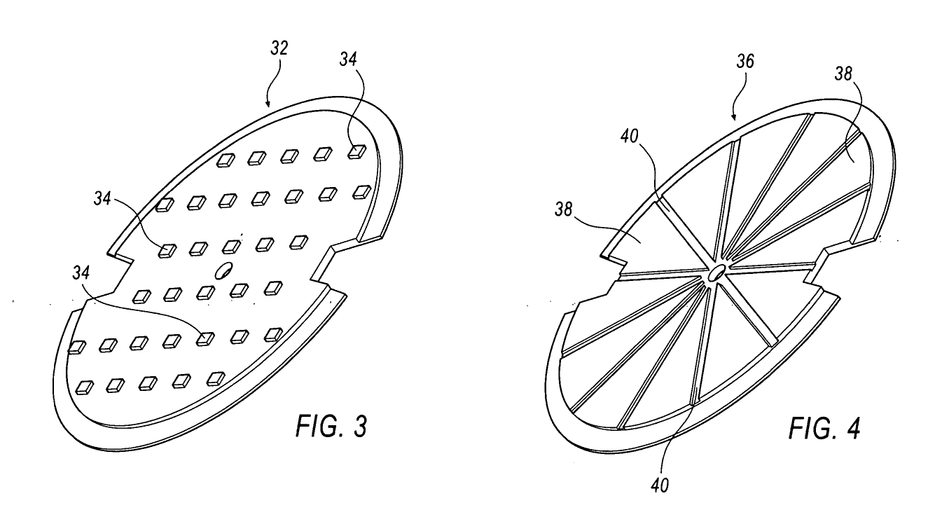

FIGS. 3-7 illustrate exemplary bonder pressure plates for controlling the bond front propagation and reducing air pockets in wafer scale bonding. For example, FIG. 3 illustrates a bonder pressure plate 32 having an array of protruded structures 34. In this case, the protruded structures 34 are arranged in an array according to a grid-like structure complementary to that of the wafer dies 29 and the pre-trenched glass substrate 12 shown in FIGS. 1A-1C. Therefore, each section of glass substrate 12 defined by the boundaries of the trenches 18 has a point of contact established by the protruded structures 34 on the bonder pressure plate 32 where a bond front is initiated. By selectively positioning the points of contact between the substrates, the direction of the bond fronts can be anticipated and controlled. The size, placement, and overall configuration of the protruded structures vary depending on, for example, the pressure plate material, the rigidness of the substrates, and the topography of the MEMS devices. The pressure plate material generally includes, but is not limited to, aluminum, stainless steel, polyurethane, Viton, Delrin, and Kapton.

FIG. 4 illustrates an alternative bonder pressure plate 36 having a vent groove design. In this case, the protruded structures 38 are a plurality of triangular wedges separated by grooves 40. In addition to controlling the bond front, the vent grooves of this particular pressure plate help to reduce air pockets by venting out trapped air between the pressure plate and the substrates.

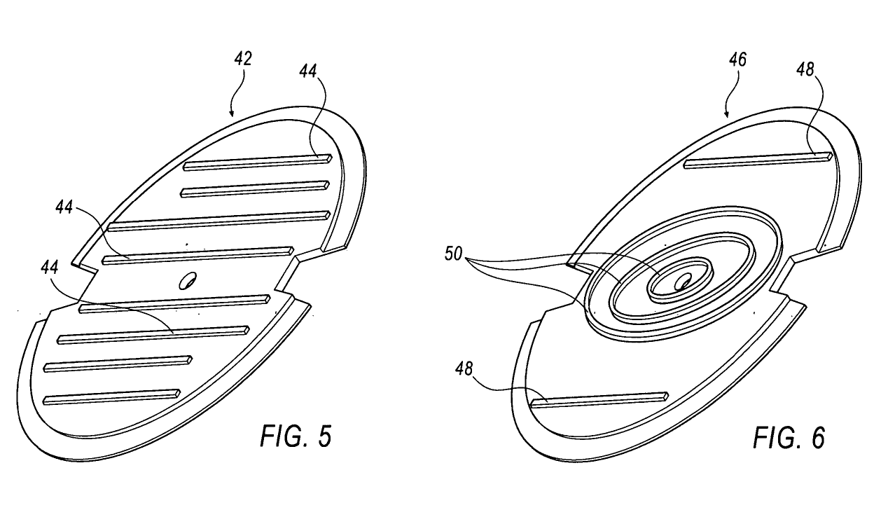

FIG. 5 illustrates another bonder pressure plate 42 with protruded structures 44 arranged in a line pattern. In this case, each line on the bonder pressure plate correlates to a row of dies 29 in the MEMS wafer. In this way, the bond front 16 is initiated and propagates from row to row.

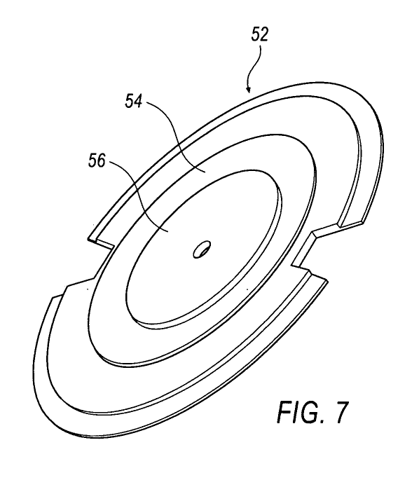

Further, the bonder pressure plate 46 of FIG. 6 includes protruded structures arranged in a line 48 and ring 50 pattern. In this way, the bond fronts 16 are initiated inward and outward from the ring 50 pattern while the outer lines 49 initiate a bond front 16 along the edges of the wafer.

FIG. 7 illustrates yet another embodiment of a bonder pressure plate 52 having protruded structures configured into an outer 54 and an inner 56 raised ring pattern. Here, the bond front initiates from the center of the wafer at the point of contact of the inner 56 ring. While the bond front propagates, the outer 54 raised ring assists the bond front as pressure is applied to the bonder pressure plate.

Alternatively, the protruded structures that establish the points of contact between two substrates may be selectively positioned on one of the substrates themselves, rather than on the bonder pressure plate. In this case, the protruded structures may be positioned according to the bonder pressure plate configurations described above, or may be arranged according to other design criteria.

While the present invention has been particularly shown and described with reference to the foregoing preferred embodiment, it should be understood by those skilled in the art that various alternatives to the embodiments of the invention described herein may be employed in practicing the invention without departing from the spirit and scope of the invention as defined in the following claims. It is intended that the following claims define the scope of the invention and that the method and system within the scope of these claims and their equivalents be covered thereby. This description of the invention should be understood to include all novel and non-obvious combinations of elements described herein, and claims may be presented in this or a later application to any novel and non-obvious combination of these elements. The foregoing embodiment is illustrative, and no single feature or element is essential to all possible combinations that may be claimed in this or a later application. Where the claims recite “a” or “a first” element of the equivalent thereof, such claims should be understood to include incorporation of one or more such elements, neither requiring nor excluding two or more such elements.

What is claimed is:

1. A system for controlling bond front propagation in wafer-scale packaging, comprising:
a first substrate;
a second substrate; and
a bonder pressure plate having protruded structures thereon to selectively establish at least one point of contact between said first and second substrates to initiate a bond front therebetween;
wherein said protruded structures are selectively configured to control the propagation of said bond front.

2. The system of claim 1, wherein said first substrate is a pre-trenched glass substrate.

3. The system of claim 1, wherein said second substrate is an optical wafer containing microelectromechanical system devices.

4. The system of claim 1, wherein said protruded structures are configured into triangular wedges separated by grooves.

5. The system of claim 1, wherein said protruded structures form a grid-like array of protruded structures on said bonder pressure plate.

6. The system of claim 1, wherein said protruded structures are a plurality of protruded lines.

7. The system of claim 1, wherein said protruded structures are arranged in a line and ring pattern.

8. The system of claim 1, wherein said protruded structures are arranged in a raised ring pattern.

9. A method for controlling bond fronts in wafer-scale packaging, comprising:
providing a first substrate and a second substrate;
initiating a bond front between said first and second substrates by selectively establishing at least one point of contact therebetween; and
establishing said at least one point of contact by applying a bonder pressure plate having protruded structures disposed thereon.

10. A method for controlling bond fronts in wafer-scale packaging, comprising:
providing a first substrate and a second substrate;
establishing at least one point of contact between said first and second substrates by selectively positioning protruded structures on either of said first and second substrates; and
initiating a bond front between said first and second substrates at said at least one point of contact therebetween.

11. An apparatus for initiating bond fronts in wafer-scale packaging, comprising:
a generally planar plate; and
a plurality of protruded structures disposed on said generally planar plate for selectively establishing at least one point of contact between a first and a second substrate.

12. The apparatus of claim 11, wherein said protruded structures are configured into triangular wedges separated by grooves.

13. The apparatus of claim 11, wherein said protruded structures form a grid-like array of protruded structures on said bonder pressure plate.

14. The apparatus of claim 11, wherein said protruded structures are a plurality of protruded lines.

15. The apparatus of claim 11, wherein said protruded structures are arranged in a line and ring pattern.

16. The apparatus of claim 11, wherein said protruded structures are arranged in a raised ring pattern.

17. An apparatus for initiating bond fronts in wafer-scale packaging, comprising:
a generally planar plate; and
a means for initiating and controlling bond front propagation between a first and a second substrate.
